(19) United States
(12) Patent Application Publication
(10) Pub. No.: US 2026/0031766 A1
(43) Pub. Date: Jan. 29, 2026

(54) ADAPTIVE BIAS CIRCUIT AND METHOD

(71) Applicant: TAIWAN SEMICONDUCTOR MANUFACTURING COMPANY, LTD., Hsinchu (TW)

(72) Inventors: Hong-Shen CHEN, Hsinchu (TW); Hsieh-Hung HSIEH, Hsinchu (TW); Tzu-Jin YEH, Hsinchu (TW)

(21) Appl. No.: 18/929,981

(22) Filed: Oct. 29, 2024

Related U.S. Application Data
(60) Provisional application No. 63/674,405, filed on Jul. 23, 2024.

(51) Int. Cl. H03F 1/30; H03F 1/02

(52) U.S. Cl. CPC H03F 1/301; H03F 1/0211; H03F 2200/171; H03F 2200/451

(57) ABSTRACT

A circuit includes first and second input terminals configured to receive a radio frequency (RF) signal, a first output terminal configured to output a direct current (DC) signal, first and second NMOS transistors coupled in parallel between a reference node and a first node and including gates capacitively coupled to the first and second input terminals, a voltage divider coupled between the first node and a power supply node, wherein the voltage divider includes a voltage tap, and a low-pass filter coupled between the voltage tap and the first output terminal. The circuit is configured to decrease a voltage level of the DC signal responsive to an increase in a power level of the RF signal.

### PRIORITY CLAIM

The present application claims the priority of U.S. Provisional Application No. 63/674,405, filed Jul. 23, 2024, which is incorporated herein by reference in its entirety.

### BACKGROUND

In many integrated circuit (IC) applications, a signal such as a radio frequency (RF) signal is amplified as part of a wireless communication operation, radar detection operation, or other such application. Corresponding amplifiers employ a variety of circuit types and arrangements such as multistage configurations. The conditions under which such amplifiers operate often include high frequencies and a wide range of operational requirements.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic diagram of an amplifier, in accordance with some embodiments.

FIGS. 1B and 1C are diagrams of amplifier operating parameters, in accordance with some embodiments.

FIG. 2 is a schematic diagram of a bias circuit, in accordance with some embodiments.

FIG. 3 is a schematic diagram of an amplifier, in accordance with some embodiments.

FIG. 4 is a schematic diagram of an amplifier, in accordance with some embodiments.

FIG. 5 is a schematic diagram of an amplifier, in accordance with some embodiments.

FIG. 6 is a flowchart of a method of operating a circuit, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, a bias circuit and method include first and second n-type metal-oxide-semiconductor (NMOS) transistors coupled in parallel between a reference node and a first node and including gates capacitively coupled to input terminals configured to receive a radio frequency (RF) signal, a voltage divider coupled between the first node and a power supply node, and a low-pass filter coupled between a voltage divider tap and an output terminal. The bias circuit is thereby configured to output a bias voltage having a voltage level that decreases with an increasing power level of the RF signal, e.g., a signal having a millimeter (mm) wavelength.

The bias circuit is thereby capable of receiving the RF signal from a first p-type metal-oxide-semiconductor (PMOS) stage of an amplifier and outputting the bias voltage to one or more additional amplifier PMOS stages so that a PMOS overdrive voltage is increased and both an output power linearity (and therefore dynamic range) and a power added efficiency (PAE) of the amplifier are enhanced compared to other approaches, e.g., those in which output power linearity is based solely on predetermined bias voltages and/or transistor dimensions.

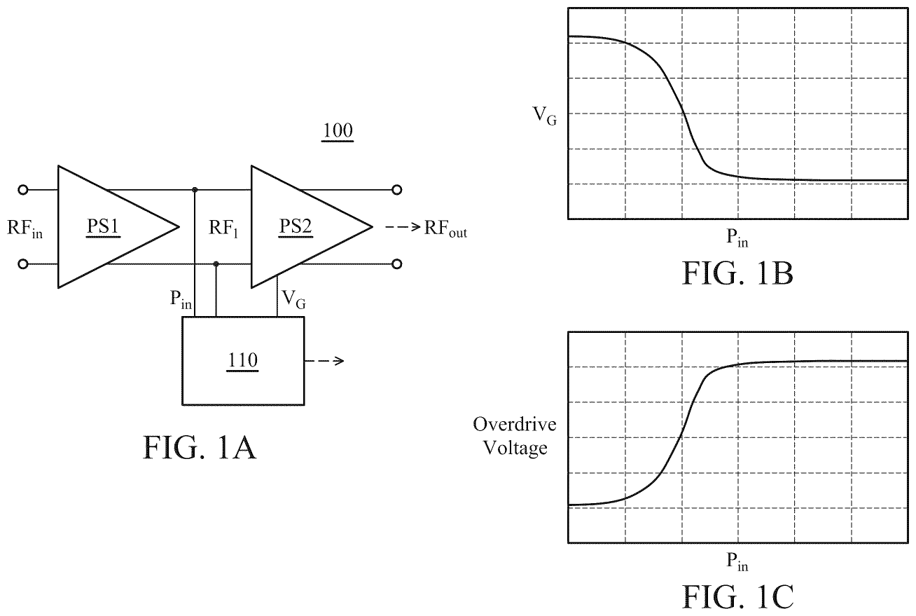

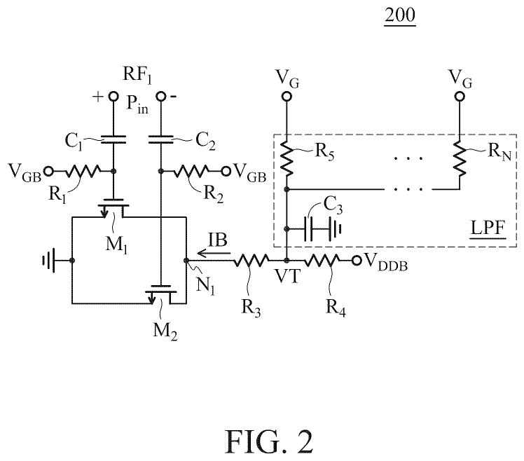

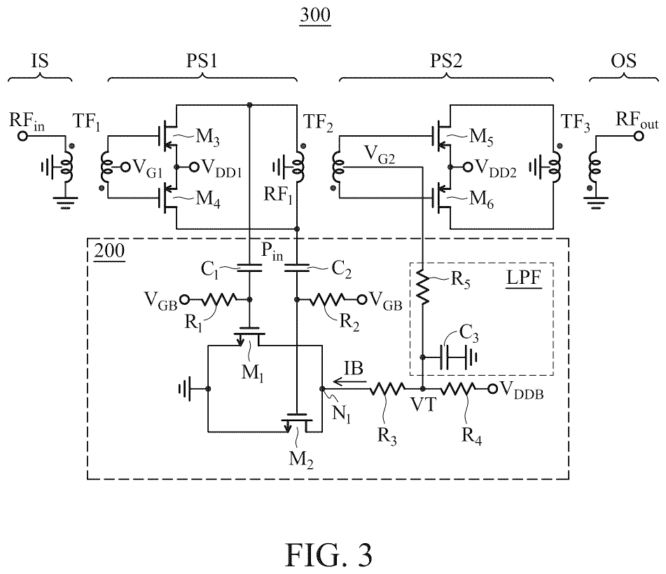

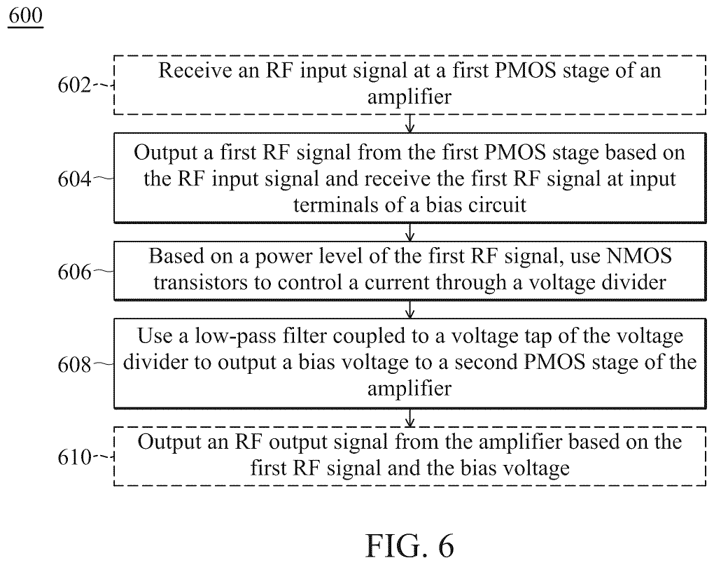

In accordance with various embodiments, FIGS. 1A-1C are a schematic diagram and corresponding operating parameters of an amplifier 100, FIG. 2 is a schematic diagram of a bias circuit 200, FIGS. 3-5 are schematic diagrams of amplifiers 300-500, and FIG. 6 is a flowchart of a method 600 of operating a circuit.

In some embodiments, one or more of amplifiers 100 or 300-500 or bias circuit 200 is some or all of an integrated circuit (IC). In some embodiments, one or more of amplifiers 100 or 300-500 or bias circuit 200 is included in another IC, e.g., a signal processor, receiver, transmitter, transceiver, or other suitable IC.

FIGS. 1A-5 are simplified for the purpose of illustration. In some embodiments, one or more of circuits 100-500 includes features in addition to those depicted in FIGS. 1A-5, e.g., one or more of a control circuit or power distribution network, that are not depicted for the purpose of clarity. Circuit elements depicted in FIGS. 1A-5 include corresponding input and output terminals that are not labeled for the purpose of clarity.

FIG. 1A is a schematic diagram of amplifier 100, in accordance with some embodiments. Amplifier 100 corresponds to a generalized embodiment including PMOS stages PS1 and PS2 in a cascade arrangement and a bias circuit 110. In some embodiments, as discussed below, amplifier 100 corresponds to one of amplifiers 300-500 and/or bias circuit 110 corresponds to bias circuit 200.

In some embodiments, amplifier 100 is referred to as a power amplifier (PA) 100, a PMOS amplifier 100, or a PMOS PA 100. In the embodiment depicted in FIG. 1A, amplifier 100 includes a total of two PMOS stages PS1 and PS2. In some embodiments, e.g., amplifiers 400 and 500 discussed below, amplifier 100 includes one or more PMOS stages in addition to PMOS stages PS1 and PS2.

As depicted in FIG. 1A, PMOS stage PS1 includes two input terminals, corresponding to input terminals of amplifier 100, and two output terminals coupled to corresponding input terminals of each of PMOS stage PS2 and bias circuit 110. Bias circuit 110 includes an output terminal coupled to an input terminal of PMOS stage PS2, also referred to as a gate terminal in some embodiments, and PMOS stage PS2 includes two output terminals corresponding to output terminals of amplifier 100.

In the embodiment depicted in FIG. 1A, PMOS stage PS1 and amplifier 100 are configured to, in operation, receive an RF input signal RFin as a differential signal on the two input terminals. In some embodiments, e.g., amplifiers 300-500 discussed below, PMOS stage PS1 and amplifier 100 include a single input terminal and PMOS stage PS1 and amplifier 100 are thereby configured to receive RF input signal RFin as a single-ended signal with respect to a reference voltage, e.g., ground.

In the embodiment depicted in FIG. 1A, PMOS stage PS2 and amplifier 100 are configured to, in operation, output an RF output signal RFout as a differential signal on the two output terminals. In some embodiments, e.g., amplifiers 300-500 discussed below, PMOS stage PS2 and amplifier 100 include a single output terminal and PMOS stage PS2 and amplifier 100 are thereby configured to output RF output signal RFout as a single-ended signal with respect to the reference voltage.

An RF signal, e.g., RF input signal RFin, RF output signal RFout, or an RF signal RF1, has a frequency ranging from 30 kilohertz (kHz) to 300 gigahertz (GHz). As the frequency of the RF signal increases, data bandwidth increases and parasitic effects, e.g., those of resistance, capacitance, and/or inductance, also increase, thereby increasing circuit complexity in some embodiments.

In some embodiments, an RF signal has a frequency ranging from 3 GHz to 300 GHz, e.g., corresponding to millimeter (mm) wavelengths. In some embodiments, an RF signal, also referred to as a D-band signal in some embodiments, has a frequency ranging from 110 GHz to 170 GHz corresponding to a wavelength ranging from 2.7 mm to 1.8 mm.

A PMOS stage, e.g., PMOS stage PS1 or PS2, is an IC configured to, in operation, amplify and output a received RF signal by including one or more PMOS transistors configured accordingly. In some embodiments, a PMOS stage is referred to as a PMOS amplifier stage, an amplifier stage, or an RF amplifier stage. The gain of a given PMOS stage is based on the voltage level of a bias voltage, e.g., a voltage Vg output from bias circuit 110, received at the gate terminal of the PMOS, and has a value that increases as the voltage level of the bias voltage decreases.

In some embodiments, a PMOS stage has a configuration corresponding to PMOS stages PS1-PS5 as depicted in FIGS. 3-5 and discussed below.

In the embodiment depicted in FIG. 1A, PMOS stage PS1 is configured to, in operation, receive a bias voltage (not shown) having a predetermined voltage level, and is thereby configured to amplify received RF input signal RFin in accordance with a predetermined gain, and output the amplified signal as RF signal RF1.

As depicted in IG. 1A, PMOS stage PS2 is configured to receive voltage Vg from bias circuit 110 and is thereby configured to amplify received RF signal RF1 in accordance with a gain that varies in response to voltage Vg by increasing in response to a decrease in the voltage level of voltage Vg, and output the amplified signal as RF output signal RFout.

Bias circuit 110 is an IC configured to, in operation, receive an RF signal, e.g., RF signal RF1, and output a direct current (DC) signal, e.g., voltage Vg, having a voltage level that varies in response to a power level Pin of the received RF signal by decreasing in value as the power level Pin increases.

A DC signal is a signal having a voltage level that is predominantly constant over time and in some embodiments includes alternating current (AC) components such as filtered RF signal or noise components having magnitudes less than the voltage level by a predetermined amount, e.g., a percentage or decibel level.

In some embodiments, bias circuit 110 is configured to receive a control voltage (not shown) having a voltage level configured to, in operation, cause bias circuit 110 to generate the DC voltage in response to power level Pin, e.g., by biasing one or more transistor gates so that the one or more transistors operate in a linear region.

In some embodiments, bias circuit 110 has a configuration corresponding to bias circuit 200 depicted in FIG. 2 and discussed below.

FIG. 1B depicts operating parameters of circuit 100, in accordance with some embodiments, that provide a non-limiting example of voltage Vg output from bias circuit 110 as a function of power level Pin. As depicted in FIG. 1B, as power level Pin increases, the voltage level of voltage level Vg decreases.

FIG. 1C depicts operating parameters of circuit 100, in accordance with some embodiments, that provide a non-limiting example of an overdrive voltage of amplifier 100 as a function of power level Pin. An overdrive voltage is an amount of a gate voltage, e.g., voltage Vg, magnitude above a threshold voltage magnitude of the one or more PMOS transistors, e.g., of PMOS stage PS2, configured to control the amplification of the signal output as RF output signal RFout. In some embodiment, the overdrive voltage is equal to |Vg|−|Vth|, where Vg is voltage Vg and Vth is the threshold voltage of the one more PMOS transistors.

As depicted in FIG. 1C, as power level Pin increases, the overdrive voltage of amplifier 100 increases. As the overdrive voltage increases, a power level of RF output signal RFout increases.

By the configuration discussed above, amplifier 100 includes bias circuit 110 configured to receive RF signal RF1 from PMOS stage PS1 and output voltage Vg to PMOS stage PS2 having a voltage level that decreases with increasing power level Pin such that the PMOS overdrive voltage is increased and both the output power linearity (and therefore dynamic range) and the PAE of amplifier 100 are enhanced compared to other approaches, e.g., those in which output power linearity is based solely on predetermined bias voltages and/or transistor dimensions.

FIG. 2 is a schematic diagram of bias circuit 200, in accordance with some embodiments. Bias circuit 200, also referred to as adaptive bis network (ABN) 200 or adaptive bias control network 200 in some embodiments, is usable as bias circuit 110 discussed above with respect to FIGS. 1A-1C.

Bias circuit 200 includes NMOS transistors M1 and M2 coupled in parallel between a reference node (depicted as ground in FIGS. 2-5) and a node N1, a voltage divider including resistive devices R3 and R4 and a voltage tap VT coupled between node N1 and power supply node VDDB. A gate of NMOS transistor M1 is (capacitively) coupled to a first input terminal (+) through a capacitive device C1 and to a control voltage terminal Vgb though a resistive device R1, a gate of NMOS transistor M2 is (capacitively) coupled to a second input terminal (−) through a capacitive device C2 and to control voltage terminal Vgb though a resistive device R2, and voltage tap VT is coupled to an output terminal Vg though a low-pass filter LPF.

Low-pass filter LPF includes a capacitive device C3 coupled between voltage tap VT and the reference node, and a resistive device R5 coupled between voltage tap VT and output terminal Vg. In some embodiments, low-pass filter LPF includes one or more additional instances of output terminal Vg and a corresponding one or more additional resistive devices, represented collectively as resistive device Rn.

Power supply node VDDB is configured to, in operation, have a power supply voltage VDDB. In various embodiments, power supply voltage VDDB is the same as or different from one or more power supply voltages distributed in an amplifier, e.g., amplifier 100, in which bias circuit 200 is included.

In operation, control voltage VGb is received at the gates of NMOS transistors M1 and M2 having a positive voltage level sufficiently large to cause a conductivity of each of NMOS transistors M1 and M2 to increase as power level Pin increases such that a current IB through the voltage divider including resistive devices R3 and R4 has a magnitude that increases as power level Pin increases. In some embodiments, control voltage VGb has the positive voltage level corresponding to each of NMOS transistors M1 and M2 operating in a linear region.

In various embodiments, control voltage VGb is received from a circuit, e.g., a control circuit or amplifier, external to and/or including bias circuit 200, or bias circuit 200 includes additional circuit elements (not shown), e.g., an additional voltage divider, configured to generate control voltage VGb from power supply voltage VDDB.

In operation, current IB flowing through resistive devices R3 and R4 causes voltage tap VT to have a voltage VT. Each instance of output terminal Vg is configured to be coupled to an amplifier element having a high input resistance such that, in operation, little to no current flows through resistive devices R5 and Rn (if present) of low-pass filter LPF, and voltage VT at voltage tap VT appears at each instance of output terminal Vg as bias voltage Vg.

A combination of control voltage VGb and power level Pin having sufficiently small magnitudes causes each of NMOS transistors to be switched off or nearly switched off such that current IB is sufficiently small to cause voltage VT and bias voltage Vg to have voltage levels at or near that of power supply voltage VDDB.

As the magnitude of power level Pin increases, each of NMOS transistors is switched on sufficiently to cause current IB to increase sufficiently to cause voltage VT and bias voltage Vg to decrease by an amount corresponding to the amount of the power level Pin increase.

Bias circuit 200 is thereby configured to receive RF signal RF1 and output voltage Vg having a voltage level that decreases with increasing power level Pin such that an amplifier, e.g., amplifier 100 discussed above, including bias circuit 200 is capable of realizing the benefits discussed above with respect to amplifier 100.

FIGS. 3-5 are schematic diagrams of amplifiers 300-500, in accordance with some embodiments. Each of amplifiers 300-500 is usable as amplifier 100 discussed above with respect to FIGS. 1A-1C and includes bias circuit 200 discussed above with respect to FIG. 2.

As depicted in FIGS. 3-5, each of amplifier 300-500 includes PMOS stages PS1 and PS2 of amplifier 100, amplifier 400 also includes a PMOS stage PS3, and amplifier 500 also includes PMOS stages PS4 and PS5. The combinations of PMOS stages PS1-PS5 are arranged between an input stage IS and an output stage OS.

As depicted in FIGS. 3-5, input stage IS includes one or two primary windings of a transformer TF1 configured to receive input RF signal RF1 discussed above, and output stage OS includes one or two secondary windings of one of transformers TF3 or TF4.

Each PMOS stage PS1-PS5 includes the secondary winding of a corresponding one of transformers TF1-TF3 including ends coupled to gates of two instances of PMOS transistors M3-M8 and a tap configured to receive one of gate voltages VG1-VG3. A first source/drain (S/D) terminal of each PMOS transistor M3-M8 is coupled to a corresponding one of power supply nodes VDD1-VDD3, and second S/D terminals are coupled to the primary winding of a corresponding one of transformers TF2-TF4 and are configured as output terminals of the corresponding PMOS stage PS1-PS5.

Each PMOS stage PS1-PS5 is thereby configured to, in operation, receive a corresponding RF input signal at the secondary winding and output a corresponding RF output signal at the corresponding primary winding and amplified by a gain based on voltage levels of the gate voltage VG1-VG3 and power supply voltage VDD1-VDD3.

Gate voltage VG1 and each of power supply voltages VDD1-VDD3 has a predetermined voltage level and in various embodiments is received from a circuit (not shown) external to or included in the corresponding amplifier 300-500.

In each of the embodiments depicted in FIGS. 3-5, PMOS stage PS1 is configured to output RF signal RF1 having power level Pin to bias circuit 200, and bias circuit 200 is configured to output bias voltage VG2 corresponding to bias voltage Vg to PMOS stage PS2, as discussed above with respect to FIGS. 1A-2.

As depicted in FIG. 3, amplifier 300 is configured in accordance with the cascade arrangement of amplifier 100 including a total of two PMOS stages PS1 and PS2 and is thereby configured to realize the benefits discussed above with respect to amplifier 100.

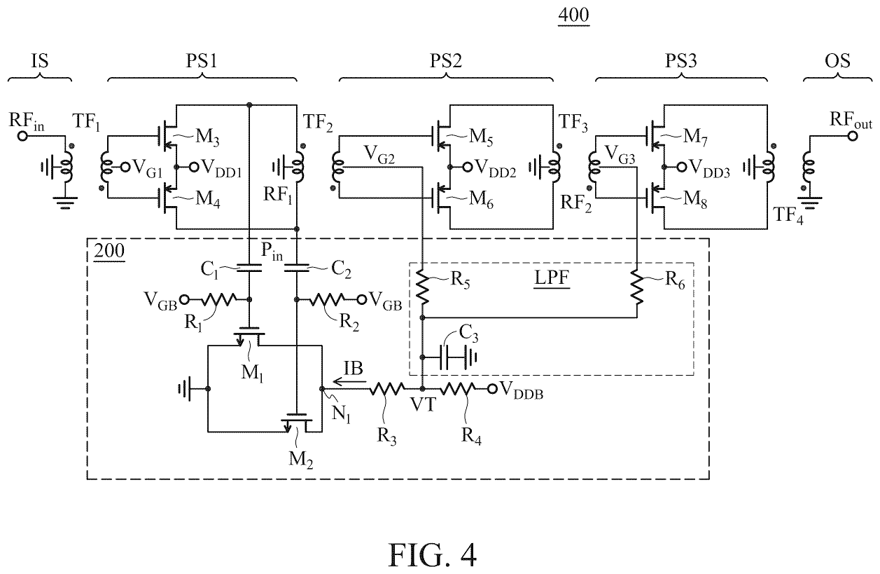

As depicted in FIG. 4, amplifier 400 is configured in accordance with the cascade arrangement of amplifier 100 including a total of three PMOS stages PS1-PS3, PMOS stage PS3 being configured to receive bias voltage VG3 corresponding to bias voltage Vg, and is thereby configured to realize the benefits discussed above with respect to amplifier 100.

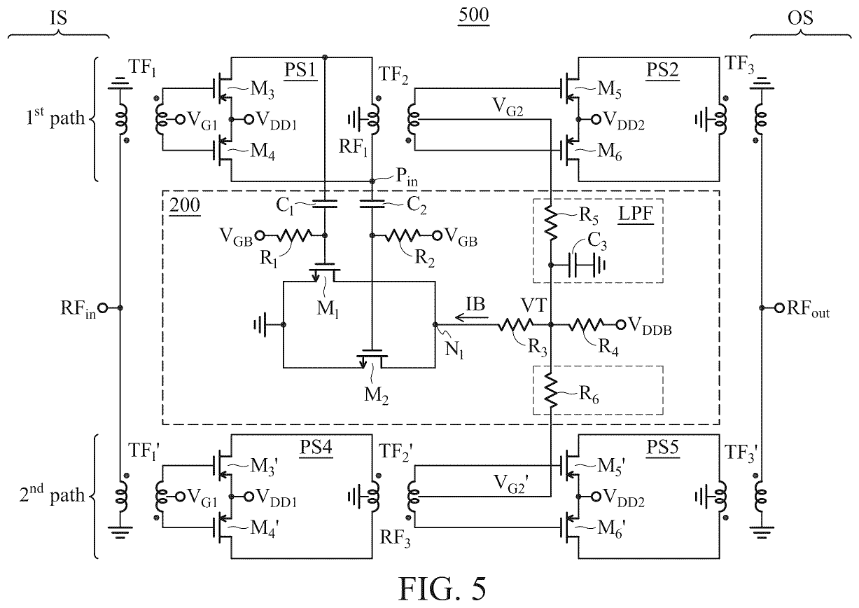

As depicted in FIG. 5, amplifier 500 is configured as a parallel arrangement including a 1^{st} path and a 2^{nd} path. The 1^{st} path is configured in accordance with the cascade arrangement of amplifier 100 including a total of two PMOS stages PS1 and PS2. The 2^{nd} path is configured in accordance with the cascade arrangement of amplifier 100 including a total of two PMOS stages PS4, analogous to PMOS stage PS1, and PS5, analogous to PMOS stage PS2 and configured to receive a bias voltage VG2′ corresponding to bias voltage Vg. Amplifier 500 is thereby configured to realize the benefits discussed above with respect to amplifier 100.

FIG. 6 is a flowchart of method 600 of operating a circuit, in accordance with some embodiments. Method 600 is usable with a bias circuit 110 or 200 and or an amplifier 100 or 300-500 discussed above with respect to FIGS. 1A-5.

The sequence in which the operations of method 600 are depicted in FIG. 6 is for illustration only; the operations of method 600 are capable of being executed in sequences that differ from that depicted in FIG. 6. In some embodiments, operations in addition to those depicted in FIG. 6 are performed before, between, during, and/or after the operations depicted in FIG. 6. In some embodiments, the operations of method 600 are a subset of a method of operating an IC, e.g., a wireless communication or radar circuit.

At operation 602, in some embodiments, an RF input signal is received at a first PMOS stage of an amplifier. In some embodiments, receiving the RF input signal includes receiving RF input signal RFin at PMOS stage PS1 of amplifier 100 or 300-500 as discussed above with respect to FIGS. 1A-1C and 3-5.

At operation 404, a first RF signal is output from the first PMOS stage in some embodiments and received at input terminals of a bias circuit. In some embodiments, outputting the first RF signal includes outputting RF signal RF1 from PMOS stage PS1 and receiving RF signal RF1 at input terminal of bias circuit 110 as discussed above with respect to FIGS. 1A-1C and 3-5.

In some embodiments, receiving the first RF signal at input terminals of the bias circuit includes receiving RF signal RF1 at input terminal of bias circuit 200 as discussed above with respect to FIGS. 2-5.

At operation 606, based on a power level of the first RF signal, NMOS transistors are used to control a current through a voltage divider. In some embodiments, using the NMOS transistors includes using NMOS transistors M1 and M2 to control current IB through the voltage divider including resistive devices R3 and R4 based on power level Pin as discussed above with respect to FIGS. 2-5.

At operation 608, a low-pass filter coupled to a voltage tap of the voltage divider is used to output a bias voltage, in some embodiments to a second PMOS stage of the amplifier. In some embodiments, using the low-pass filter includes using low-pass filter LPF coupled to voltage tap VT to output bias voltage Vg as discussed above with respect to FIGS. 2-5.

In some embodiments, outputting the bias voltage to the second PMOS stage of the amplifier includes outputting one or more of bias voltages Vg2, Vg3, or Vg2′ to the corresponding one or more of PMOS stages PS2-PS5 as discussed above with respect to FIGS. 3-5.

At operation 610, in some embodiments, an RF output signal is output from the amplifier based on the first RF signal and the bias voltage. In some embodiments, outputting the RF output signal includes outputting RF output signal RFout from one of amplifiers 100 or 300-500 as discussed above with respect to FIGS. 1A-1C and 3-5.

By executing some or all of the operations of method 600, a bias circuit receives and RF signal and outputs a bias voltage having a voltage level that decreases with an increasing power level of the RF signal such that an amplifier including the bias circuit is capable of realizing the benefits discussed above with respect to FIGS. 1A-5.

In some embodiments, a circuit includes first and second input terminals configured to receive an RF signal, a first output terminal configured to output a DC signal, first and second NMOS transistors coupled in parallel between a reference node and a first node and including gates capacitively coupled to the first and second input terminals, a voltage divider coupled between the first node and a power supply node, wherein the voltage divider includes a voltage tap, and a low-pass filter coupled between the voltage tap and the first output terminal, wherein the circuit is configured to decrease a voltage level of the DC signal responsive to an increase in a power level of the RF signal. In some embodiments, the circuit includes a control voltage terminal, a first resistive device coupled between the control voltage terminal and the gate of the first NMOS transistor, and a second resistive device coupled between the control voltage terminal and the gate of the second NMOS transistor. In some embodiments, the voltage divider includes first and second resistive devices coupled together at the voltage tap. In some embodiments, the low-pass filter includes a first resistive device coupled between the voltage tap and the first output terminal and a capacitive device coupled between the voltage tap and the reference node. In some embodiments, the low-pass filter includes a second output terminal and a second resistive device coupled between the voltage tap and the second output terminal. In some embodiments, the low-pass filter includes a third output terminal and a third resistive device coupled between the voltage tap and the third output terminal. In some embodiments, the RF signal has a millimeter wavelength. In some embodiments, the first and second input terminals are coupled to output terminals of a first PMOS amplifier stage, and the first output terminal is coupled to an input terminal of a second PMOS amplifier stage coupled in series with the first PMOS amplifier stage.

In some embodiments, an amplifier includes a first PMOS stage configured to receive a first RF signal and output a second RF signal based on the first RF signal, a second PMOS stage configured to receive the second RF signal and output a third RF signal based on the second RF signal, and a bias circuit including first and second NMOS transistors coupled in parallel between a reference node and a first node, first and second capacitive devices coupled between gates of the first and second NMOS transistors and output terminals of the first PMOS stage, a voltage divider coupled between the first node and a first power supply node, wherein the voltage divider includes a voltage tap, and a low-pass filter coupled between the voltage tap and an input terminal of the second PMOS stage. In some embodiments, the bias circuit includes a first resistive device coupled between the gate of the first NMOS transistor and a control voltage terminal configured to receive a control voltage and a second resistive device coupled between the gate of the second NMOS transistor and the control voltage terminal, wherein the control voltage has a voltage level configured to cause a conductivity of each of the first and second NMOS transistors to vary responsive to a power level of the second RF signal. In some embodiments, each of the first and second PMOS stages includes a transformer winding configured to receive the corresponding first or second RF signal, a first PMOS transistor coupled between a second power supply node and a first output terminal and comprising a first gate coupled to a first end of the transformer winding, and a second PMOS transistor coupled between the second power supply node and a second output terminal and comprising a second gate coupled to a second end of the transformer winding, wherein the input terminal of the second PMOS stage includes a tap on the transformer winding. In some embodiments, the voltage divider includes first and second resistive devices coupled together at the voltage tap, and the low-pass filter includes a third resistive device coupled between the voltage tap and the input terminal of the second PMOS stage and a third capacitive device coupled between the voltage tap and the reference node. In some embodiments, the amplifier includes a third PMOS stage configured to receive the third RF signal and output a fourth RF signal based on the third RF signal, wherein the low-pass filter includes a fourth resistive device coupled between the voltage tap and an input terminal of the third PMOS stage. In some embodiments, the amplifier includes a third PMOS stage configured to receive the first RF signal and output a fourth RF signal based on the first RF signal, and a fourth PMOS stage configured to receive the fourth RF signal and output the third RF signal further based on the fourth RF signal, wherein the low-pass filter includes a fourth resistive device coupled between the voltage tap and an input terminal of the fourth PMOS stage. In some embodiments, the first through third RF signals have a frequency ranging from 3 GHz to 300 GHz.

In some embodiments, a method of operating a circuit includes receiving a first RF signal at first and second input terminals of a bias circuit, wherein the first and second input terminals are capacitively coupled to gates of first and second NMOS transistors arranged in parallel, in response to a power level of the first RF signal, using the first and second NMOS transistors to control a current through a voltage divider coupled between the first and second NMOS transistors and a power supply node, and using a low-pass filter coupled to a voltage tap of the voltage divider to output a bias voltage from the bias circuit, wherein outputting the bias voltage from the bias circuit includes decreasing a voltage level of the bias voltage in response to an increase in a power level of the first RF signal. In some embodiments, using the first and second NMOS transistors to control the current through the voltage divider includes receiving a control voltage at the gate of each of the first and second transistors. In some embodiments, the method includes receiving an RF input signal at a first PMOS stage of an amplifier, outputting the first RF signal from the first PMOS stage based on the RF input signal, receiving the bias voltage at a second PMOS stage of the amplifier, and outputting an RF output signal from the amplifier based on the first RF signal and the bias voltage. In some embodiments, receiving the bias voltage at the second PMOS stage includes receiving the bias voltage at a third PMOS stage of the amplifier, and outputting the RF output signal from the amplifier is further based on a second RF signal output from the third PMOS stage. In some embodiments, receiving the first RF signal includes receiving the first RF signal having a millimeter wavelength.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A circuit comprising:
first and second input terminals configured to receive a radio frequency (RF) signal;
a first output terminal configured to output a direct current (DC) signal;
first and second NMOS transistors coupled in parallel between a reference node and a first node and comprising gates capacitively coupled to the first and second input terminals;
a voltage divider coupled between the first node and a power supply node, wherein the voltage divider comprises a voltage tap; and
a low-pass filter coupled between the voltage tap and the first output terminal,
wherein the circuit is configured to decrease a voltage level of the DC signal responsive to an increase in a power level of the RF signal.

2. The circuit of claim 1, further comprising:
a control voltage terminal;
a first resistive device coupled between the control voltage terminal and the gate of the first NMOS transistor; and
a second resistive device coupled between the control voltage terminal and the gate of the second NMOS transistor.

3. The circuit of claim 1, wherein
the voltage divider comprises first and second resistive devices coupled together at the voltage tap.

4. The circuit of claim 1, wherein the low-pass filter comprises:
a first resistive device coupled between the voltage tap and the first output terminal; and
a capacitive device coupled between the voltage tap and the reference node.

5. The circuit of claim 4, wherein the low-pass filter further comprises:
a second output terminal; and
a second resistive device coupled between the voltage tap and the second output terminal.

6. The circuit of claim 5, wherein the low-pass filter further comprises:
a third output terminal; and
a third resistive device coupled between the voltage tap and the third output terminal.

7. The circuit of claim 1, wherein
the RF signal has a millimeter wavelength.

8. The circuit of claim 1, wherein
the first and second input terminals are coupled to output terminals of a first PMOS amplifier stage, and
the first output terminal is coupled to an input terminal of a second PMOS amplifier stage coupled in series with the first PMOS amplifier stage.

9. An amplifier comprising:
a first PMOS stage configured to receive a first radio frequency (RF) signal and output a second RF signal based on the first RF signal;
a second PMOS stage configured to receive the second RF signal and output a third RF signal based on the second RF signal; and
a bias circuit comprising:
first and second NMOS transistors coupled in parallel between a reference node and a first node;
first and second capacitive devices coupled between gates of the first and second NMOS transistors and output terminals of the first PMOS stage;
a voltage divider coupled between the first node and a first power supply node, wherein the voltage divider comprises a voltage tap; and
a low-pass filter coupled between the voltage tap and an input terminal of the second PMOS stage.

10. The amplifier of claim 9, wherein the bias circuit further comprises:
a first resistive device coupled between the gate of the first NMOS transistor and a control voltage terminal configured to receive a control voltage; and
a second resistive device coupled between the gate of the second NMOS transistor and the control voltage terminal,
wherein the control voltage has a voltage level configured to cause a conductivity of each of the first and second NMOS transistors to vary responsive to a power level of the second RF signal.

11. The amplifier of claim 9, wherein each of the first and second PMOS stages comprises:
a transformer winding configured to receive the corresponding first or second RF signal;
a first PMOS transistor coupled between a second power supply node and a first output terminal and comprising a first gate coupled to a first end of the transformer winding; and
a second PMOS transistor coupled between the second power supply node and a second output terminal and comprising a second gate coupled to a second end of the transformer winding,
wherein the input terminal of the second PMOS stage comprises a tap on the transformer winding.

12. The amplifier of claim 9, wherein
the voltage divider comprises first and second resistive devices coupled together at the voltage tap, and
the low-pass filter comprises:
a third resistive device coupled between the voltage tap and the input terminal of the second PMOS stage; and
a third capacitive device coupled between the voltage tap and the reference node.

13. The amplifier of claim 12, further comprising:
a third PMOS stage configured to receive the third RF signal and output a fourth RF signal based on the third RF signal,
wherein the low-pass filter further comprises:
a fourth resistive device coupled between the voltage tap and an input terminal of the third PMOS stage.

14. The amplifier of claim 12, further comprising:
a third PMOS stage configured to receive the first RF signal and output a fourth RF signal based on the first RF signal; and
a fourth PMOS stage configured to receive the fourth RF signal and output the third RF signal further based on the fourth RF signal,
wherein the low-pass filter further comprises:
a fourth resistive device coupled between the voltage tap and an input terminal of the fourth PMOS stage.

15. The amplifier of claim 9, wherein
the first through third RF signals have a frequency ranging from 3 gigahertz (GHz) to 300 GHz.

16. A method of operating a circuit, the method comprising:
receiving a first radio frequency (RF) signal at first and second input terminals of a bias circuit, wherein the first and second input terminals are capacitively coupled to gates of first and second NMOS transistors arranged in parallel;
in response to a power level of the first RF signal, using the first and second NMOS transistors to control a current through a voltage divider coupled between the first and second NMOS transistors and a power supply node; and
using a low-pass filter coupled to a voltage tap of the voltage divider to output a bias voltage from the bias circuit,
wherein the outputting the bias voltage from the bias circuit comprises decreasing a voltage level of the bias voltage in response to an increase in a power level of the first RF signal.

17. The method of claim 16, wherein
the using the first and second NMOS transistors to control the current through the voltage divider comprises receiving a control voltage at the gate of each of the first and second transistors.

18. The method of claim 16, further comprising:
receiving an RF input signal at a first PMOS stage of an amplifier;
outputting the first RF signal from the first PMOS stage based on the RF input signal;
receiving the bias voltage at a second PMOS stage of the amplifier; and
outputting an RF output signal from the amplifier based on the first RF signal and the bias voltage.

19. The method of claim 18, wherein
the receiving the bias voltage at the second PMOS stage comprises receiving the bias voltage at a third PMOS stage of the amplifier, and
the outputting the RF output signal from the amplifier is further based on a second RF signal output from the third PMOS stage.

20. The method of claim 16, wherein
the receiving the first RF signal comprises receiving the first RF signal having a millimeter wavelength.
